(19) United States
(12) Patent Application Publication
(10) Pub. No.: US 2015/0138900 A1
(43) Pub. Date: May 21, 2015

(54) DATA STORAGE DEVICE AND OPERATING METHOD THEREOF

(71) Applicant: SK hynix Inc., Gyeonggi-do (KR)

(72) Inventor: Haegi CHOI, Gyeonggi-do (KR)

(73) Assignee: SK hynix Inc., Gyeonggi-do (KR)

(21) Appl. No.: 14/157,283

(22) Filed: Jan. 16, 2014

(30) Foreign Application Priority Data
Nov. 18, 2013 (KR) 10-2013-0139913

(51) Int. Cl. G11C 7/00

(52) U.S. Cl. CPC G11C 7/00
USPC 365/189.011

(57) ABSTRACT

An operating method of a data storage device includes performing a read operation on a nonvolatile memory device based on a read request and a logical address from a host device, determining whether one or more physical addresses, which correspond to one or more logical addresses continuous to the logical address, are continuous to a physical address corresponding to the logical address, and prefetching data stored in a region of the nonvolatile memory device, corresponding to the one or more physical addresses, when the one or more physical addresses are determined to be continuous.

### CROSS-REFERENCES TO RELATED APPLICATION

The present application claims priority under 35 U.S.C. 119(a) to Korean application number 10-2013-0139913, filed on Nov. 18, 2013, in the Korean Intellectual Property Office, which is incorporated herein by reference in its entirety.

### BACKGROUND

1. Technical Field

Various embodiments of the present invention relate to a data storage device, and more particularly, to a prefetch operation of a data storage device.

2. Related Art

Recently, the paradigm for computer surroundings has changed into a ubiquitous computing in which computer systems may be used anytime and anywhere. Thus, the use of portable electronic devices such as mobile phones, digital cameras, and laptop computers has rapidly increased. In general, such portable electronic devices use a data storage device that uses a memory device. The data storage device is used as a main memory device or an auxiliary memory device for the portable electronic devices.

Since the data storage device using a memory device has no mechanical driver, the data storage device has excellent stability and durability. Furthermore, the data storage device has relatively high access speed and relatively low power consumption. The data storage device having such advantages may include a Universal Serial Bus (USB) memory device, a memory card having various interfaces, and a Solid-State Drive (SSD).

According to the recent trend, data storage devices are developed to perform a high-speed operation. Thus, operating methods for more quickly transmitting data to the outside of a data storage device are in demand, when the data storage device receives a data read request from the outside.

### SUMMARY

Various embodiments of the present invention are directed to a data storage device capable of more quickly perform data transmission, and an operating method thereof.

In an embodiment of the present invention, an operating method of a data storage device may include performing a read operation on a nonvolatile memory device based on a read request and a logical address from a host device, determining whether one or more physical addresses, which correspond to one or more logical addresses continuous to the logical address, are continuous to a physical address corresponding to the logical address, and prefetching data stored in a region of the nonvolatile memory device, corresponding to the one or more physical addresses, when the one or more physical addresses are determined to be continuous.

In an embodiment of the present invention, a data storage device may include a nonvolatile memory device and a controller. The controller may perform a read operation on the nonvolatile memory device based on a read request and a logical address from a host device, determine whether one or more physical addresses corresponding to one or more logical addresses continuous to the logical address are continuous to a physical address corresponding to the logical address, and prefetch data stored in a region of the nonvolatile memory device, corresponding to the one or more physical addresses, when the one or more physical addresses are determined to be continuous.

In an embodiment of the present invention, a data storage device may include a plurality of nonvolatile memory chips and a controller. The controller may perform a read operation on any one of the nonvolatile memory chips based on a read request and a logical address from a host device, determine whether one or more physical addresses corresponding to one or more logical addresses continuous to the logical address are continuous to a physical address corresponding to the logical address, and prefetch data of a region corresponding to the one or more physical addresses when the one or more physical addresses are determined to be continuous.

### BRIEF DESCRIPTION OF THE DRAWINGS

Features, aspects, and embodiments are described in conjunction with the attached drawings, in which:

FIG. 1 is a block diagram illustrating a data processing system including a data storage device according to an embodiment of the present invention;

FIG. 2 is a diagram for explaining a normal read operation of the data storage device according to the embodiment of the present invention;

FIG. 3 is a flowchart for explaining an operating method of the data storage device according to the embodiment of the present invention;

FIG. 4 is a diagram illustrating an address mapping table to promote understanding of the operating method of FIG. 3;

FIG. 5 is a timing diagram for explaining an operating method of a data processing system including the data storage device according to the embodiment of the present invention.

FIG. 6 is a block diagram illustrating a data processing system including a data storage device according to another embodiment of the present invention; and

FIG. 7 is a timing diagram for explaining an operating method of the data processing system including the data storage device according to the embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

The drawings are not necessarily to scale and in some instances, proportions may have been exaggerated in order to clearly illustrate features of the embodiments. In this specification, specific terms have been used. The terms are used to describe the present invention, and are not used to qualify the sense or limit the scope of the present invention. Throughout the disclosure, reference numerals correspond directly to the like numbered parts in the various figures and embodiments of the present invention.

In this specification, ‘and/or’ represents that one or more of components arranged before and after ‘and/or’ is included. Furthermore, ‘connected/coupled’ represents that one component is directly coupled to another component or indirectly coupled through another component. In this specification, a singular form may include a plural form as long as it is not specifically mentioned in a sentence. Furthermore, ‘include/comprise’ or ‘including/comprising’ used in the specification represents that one or more components, steps, operations, and elements exists or are added.

Hereafter, the exemplary embodiments of the present invention will be described with reference to the drawings.

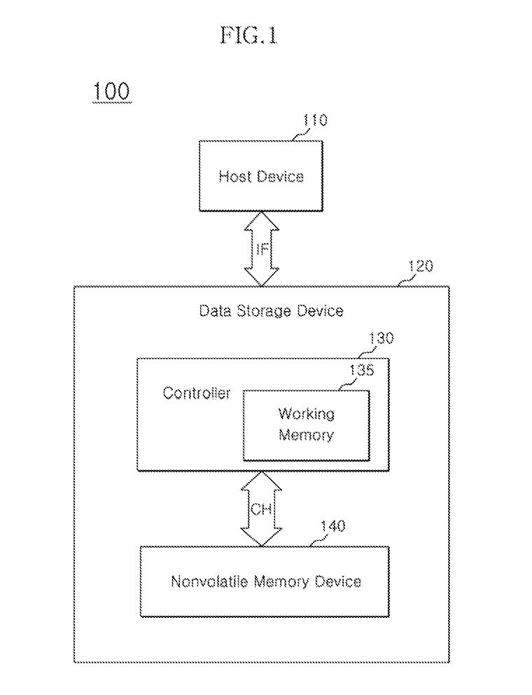

FIG. 1 is a block diagram illustrating a data processing system 100 including a data storage device 120 according to an embodiment of the present invention. Referring to FIG. 1, the data processing system 100 may include a host device 110 and the data storage device 120.

For example, the host device 110 may include portable electronic devices such as a mobile phone and an MP3 player or electronic devices such as a laptop or a desktop computer, a game player, a TV, and a beam projector.

The data storage device 120 may operate in response to a request of the host 110. The data storage device 120 may store data processed by the host device 110. That is, the data storage device 120 may be used as a main storage medium or an auxiliary memory medium of the host device 110.

The data storage device 120 may perform a data prefetch operation. For example, the data storage device 120 may previously perform a read operation before receiving a read request from the host device 110. For example, the data storage device 120 may temporarily store data transmitted through a previous read operation in a working memory 135, before receiving a next read request from the host device 110. For example, when receiving a read request from the host device 110 the data storage device 120 may transmit prefetched data.

The host device 110 and the data storage device 120 may be coupled through a host interface IF. The host interface IF may include any one of standard interfaces such as an advanced technology attachment (ATA), a serial ATA (SATA), a parallel ATA (PATA), a universal serial bus (USB) a small computer system interface (SCSI), an enhanced small device interface (ESDI), a FireWire, an integrated drive electronics (IDE), a peripheral component interconnect-express (PCI-express), a multi media card (MMC), and a universal flash storage (UFS). The host device 110 and the data storage device 120 may exchange a read/write request and data through the host interface IF.

The data storage device 120 may include a controller 130 and a nonvolatile memory device 140.

The controller 130 may control overall operations of the data storage device 120. For example, the controller 130 may control the nonvolatile memory device 140 in response to a request from the host device 100. Furthermore, the controller 130 may provide data transmitted from the nonvolatile memory device 140 to the host device 110. For another example, the controller 130 may store data provided from the host device 110 in the nonvolatile memory device 140. For this operation, the controller 130 may control read, write, and erase operations for the nonvolatile memory device 140.

When a read request (i.e., a current read request) is made with a logical address (i.e., a current logical address) by the host device 110, the controller 130 may determine whether a physical address of the nonvolatile memory device 140, which is mapped to a successive logical address, is continuous to a current physical address mapped to the current logical address. When the physical address is determined to be continuous, the controller 130 may prefetch data corresponding to the physical address while a read operation corresponding to the current read request is performed. Meanwhile, one or more physical addresses may be determined at once. Similarly, the data corresponding to the one or more physical addresses may be prefetched at the same time. The controller 130 may check the range in which the one or more physical addresses are continuous, and set the range of the continuous physical addresses to a prefetch range.

The controller 130 may drive firmware for controlling overall operations of the data storage device 120. The firmware and data required for driving the firmware may be loaded onto the working memory 135 and then driven.

The working memory 135 may store the firmware and data required for the operation of the controller 130. The working memory 135 may temporarily store data to be transmitted to the nonvolatile memory device 140 from the host device 110 or to the host device 110 from the nonvolatile memory device 140. That is, the working memory 135 may operate as a buffer memory device or a cache memory device.

The nonvolatile memory device 140 and the controller 130 may be coupled through a channel CH. The nonvolatile memory device 140 and the controller 130 may exchange a read or write command or data through the channel CH. The nonvolatile memory device 140 may perform a read or write operation by the page in which a plurality of memory cells are arranged. The nonvolatile memory device 140 may perform an erase operation by the block in which a plurality of pages are arranged. Furthermore, the nonvolatile memory device 140 may not perform an overwrite operation due to the structural characteristic thereof. That is, a memory cell of the nonvolatile memory device 140, in which data is stored, may be erased to store new data. Due to such characteristics of the nonvolatile memory device 140, the controller 130 may drive additional firmware referred to as a flash translation layer (FTL).

The FTL may manage read and write operations of the nonvolatile memory device 140 so that the data storage device 120 operates in response to an access request from a file system (not illustrated) of the host device 110, for example, a read or write request. Furthermore, the FTL may manage additional operations based on the characteristics of the nonvolatile memory device 140. For example, the FTL may manage various operations such as a garbage collection operation, a ware-leveling operation, and a bad block management operation.

When the host device 110 accesses the data storage device 120, for example, when a read or write operation is requested, the host device 110 may provide a logical address LA to the data storage device 120. The controller 130 may convert the provided logical address into a physical address PA of the nonvolatile memory device 140, and perform the requested operation based on the physical address PA. For such an address conversion operation, address conversion data (i.e., an address mapping table) may be needed. The address mapping table may be managed by the FTL. The address mapping table may be stored in the working memory 135.

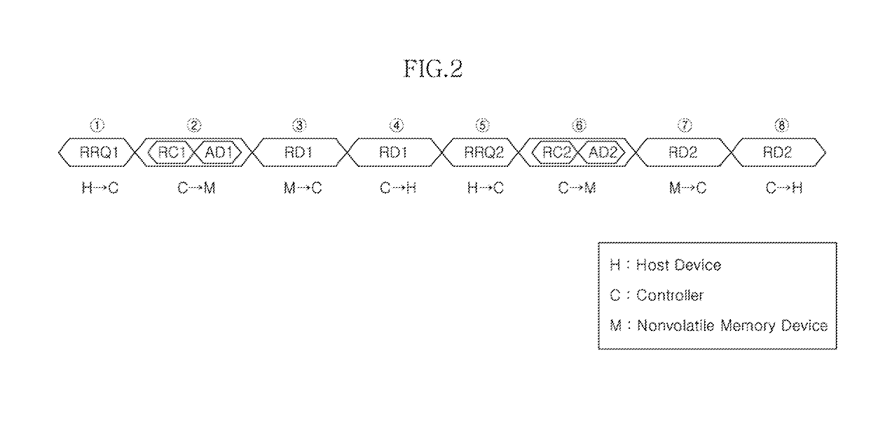

FIG. 2 is a diagram for explaining a normal read operation of the data storage device 100 shown in FIG. 1. Referring to FIG. 2, a flow of signals, which are generated while the data storage device 120 of FIG. 1 repeats the normal read operation, is expressed on the time axis.

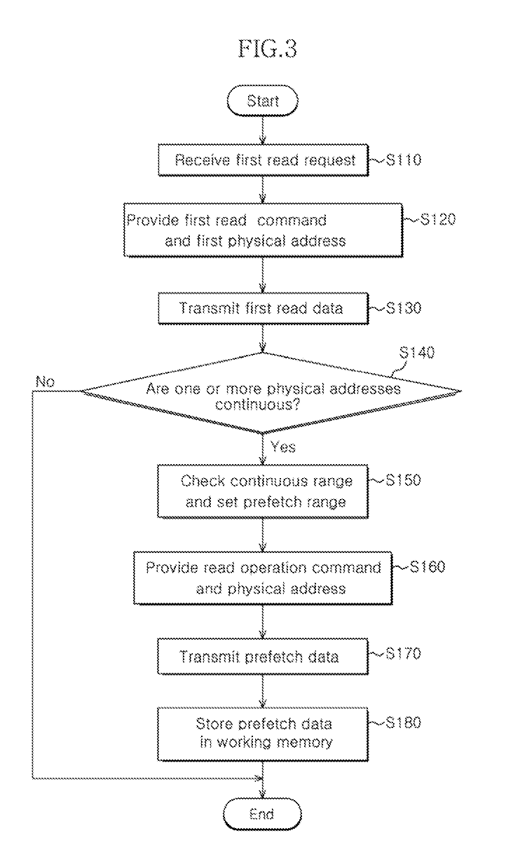

The data storage device 120 may perform a normal read operation without performing a prefetch operation. For example, the data storage device 120 may determine whether or not to perform a prefetch operation according to an operating method, which will be described with reference to FIG. 3. When determining not to perform a prefetch operation, the data storage device 120 may perform a normal read operation. The data storage device 120 may perform a normal read operation of receiving a read request from the host device 110 and transmitting data for which the read request is made.

The data storage device 120 may receive a first read request RRQ1 from the host device 110 (\textcircled{1}). Although not illustrated, the data storage device 120 may receive a logical address corresponding to the first read request RRQ1 from the host device 110. The FTL of the controller 130 may perform an address mapping operation on a logical address provided from the host device 110. The controller 130 may convert the provided logical address into a first physical address AD1 of the nonvolatile memory device 140, corresponding to the logical address, using the mapping table.

The controller 130 may provide a first read command RC1 and the first physical address AD1 to the nonvolatile memory device 140 (\textcircled{2}).

The nonvolatile memory device 140 may transmit first read data RD1, which is stored in a region corresponding to the provided first physical address AD1, to the controller 130 (\textcircled{3}).

The controller 130 may transmit the first read data RD1 to the host device 110 (\textcircled{4}).

The data storage device 120 may subsequently receive a second read request RRQ2 from the host device 110 (\textcircled{5}). A process in which the data storage device 120 performs a read operation in response to the second read request RRQ2 may be performed in the same manner as the process of \textcircled{1} to \textcircled{4}. The controller 130 may provide a second read command RC2 and a second physical address AD2 to the nonvolatile memory device 140 (\textcircled{6}). The nonvolatile memory device 140 may transmit second read data RD2, stored in a region corresponding to the provided second physical address AD2, to the controller 130 (\textcircled{7}). The controller 130 may transmit the second read data RD2 to the host device 110 (\textcircled{8}).

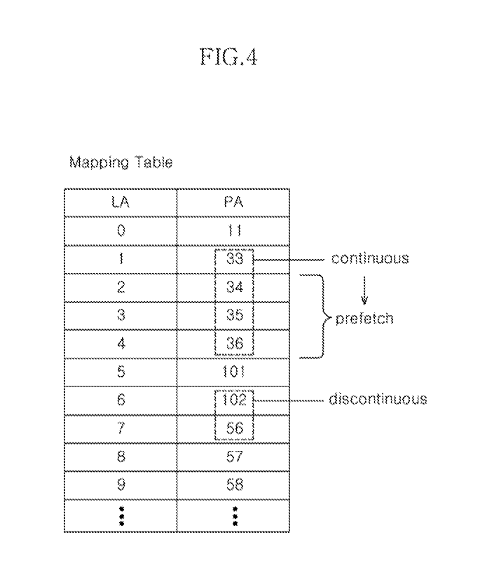

FIG. 3 is a flowchart for explaining an operating method of the data storage device according to an embodiment of the present invention. FIG. 3 illustrates a process in which the data storage device 120 performs a normal operation and a data prefetch operation. FIG. 4 is a diagram illustrating an address mapping table for explaining the operating method shown in FIG. 3. Hereafter, the operating method will be described in detail with reference to FIGS. 1, 3, and 4.

The data storage device 120 may determine whether or not to perform a prefetch operation, before performing the prefetch operation. The controller 130 of the data storage device 120 to perform a prefetch operation may previously perform a read operation (e.g., the process of \textcircled{6} and of \textcircled{7} FIG. 2) on the nonvolatile memory device 140, before receiving a read request (e.g., the second read request RRQ2 of FIG. 2) from the host device 110. The controller 130 performing a prefetch operation may temporarily store data (e.g., the second read data RD2 of FIG. 2) transmitted through the read operation (e.g., the process of \textcircled{6} and \textcircled{7} of FIG. 2), until a read request (e.g., the second read request RRQ2 of FIG. 2) is received from the host device 110.

At step S110, the controller 130 may receive a first read request from the host device 110. The controller 130 may receive a logical address corresponding to the first read request from the host device 110.

At step S120, the controller 130 may provide a first read command RC1 and a first physical address AD1 to the nonvolatile memory device 140.

At step S130, the controller 130 may receive first read data RD1 stored in a region corresponding to the first physical address AD1 from the nonvolatile memory device 140, and transmit the received first read data RD1 to the host device 110.

At step S140, the controller 130 may determine whether to perform a prefetch operation. Specifically, the controller 130 may determine whether one or more physical addresses of the nonvolatile memory device 140, which correspond to one or more logical addresses continuous to the provided logical address, are continuous to the first physical address AD1 corresponding to the logical address received from the host device 110. When the controller 130 determines that the one or more physical addresses are continuous, that is, when the controller 130 determines to perform a prefetch operation (Yes), the procedure may proceed to step S150. When the controller 130 determines that the one or more physical addresses are discontinuous, that is, when the controller 130 determines not to perform a prefetch operation (No), the procedure may be ended.

Referring to the address mapping table shown in FIG. 4, the data storage device 120 may receive a read request for a logical address (LA=1) from the host device 110. A physical address corresponding to the logical address (LA=1) is 33 (PA=33). The controller 130 may determine that physical addresses (PA=34, 35, . . . ) corresponding to logical addresses (LA=2, 3, . . . ) continuous to the provided logical address (LA=1) are continuous to the physical address (PA=33). In this case, the controller 130 may perform the following procedure (from step S150) to perform a prefetch operation.

For another example, the data storage device 120 may receive a read request for a logical address (LA=6) from the host device 110. Referring to the address mapping table, a physical address corresponding to the logical address (LA=6) is 102 (PA=102). The controller 130 may determine that physical addresses (PA=56, 57, . . . ) corresponding to logical addresses (LA=7, 8, . . . ) continuous to the provided logical address (LA=6) are discontinuous from the physical address (PA=102). In this case, the controller 130 may perform a normal operation (e.g., the process of steps S120 and S130) for the logical address (LA=6), and may not perform a prefetch operation.

At step S150, the controller 130 may check the range in which one or more physical addresses are continuous, and set the continuous range to a prefetch range. In the above-described example, since the physical addresses from the physical address (PA=33) corresponding to the logical address (LA=1) to the physical address (PA=36) corresponding to the logical address (LA=4) are continuous, the controller 130 may set a prefetch range from the physical address (PA=34) to the physical address (PA=36).

At step S160, the controller 130 may provide a read command and a physical address corresponding to the prefetch range to the nonvolatile memory device 140. In the above-described example, the controller 130 may provide the read command for the physical address (PA=34), to the nonvolatile memory device 140.

At step S170, the nonvolatile memory device 140 may transmit data stored in a region corresponding to the provided physical address PAD, to the controller 130. Hereafter, the data may be referred to as prefetch data PD. In the above-described example, the nonvolatile memory device 140 may transmit the prefetch data PD stored in the region corresponding to the physical address (PA=34) to the controller 130.

At step S180, the controller 130 may store the transmitted prefetch data PD in the working memory 135 of FIG. 1. The controller 130 may store the prefetch data PD until a new read request is received from the host device 110.

When the prefetch range is set to a plurality of physical addresses, steps S160 to S180 may be repetitively performed until the prefetch operation for the entire prefetch range is completed. In the above-described example, steps S160 to S180 may be repetitively performed at the other physical′ addresses (PA=35 and 36).

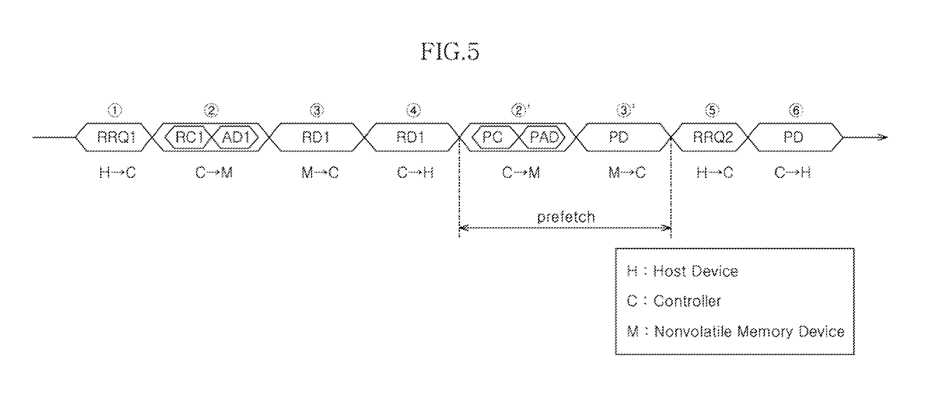

FIG. 5 is a timing diagram for explaining an operating method of a data processing system including the data storage device according to the embodiment of the present invention. FIG. 5 simply illustrates a read operation of the data processing system 100 shown in FIG. 1. In FIG. 5, it is assumed that the data storage device 120 determined to perform a prefetch operation according to the process described with reference to FIG. 3. Thus, the data storage device 120 may perform a normal read operation and a prefetch operation. FIG. 5 illustrates that the controller 130 provides one read command PC and one address PAD when performing a prefetch operation. However, when the prefetch range is set to a plurality of physical addresses, the controller 130 may provide read commands PCs for the respective physical addresses PADs.

Hereafter, referring to FIGS. 1 to 5, the operating method will be described in detail.

The data storage device 120 may receive a first read request RRQ1 from the host device 110 (\textcircled{1}). The controller 130 may perform a normal read operation (process of \textcircled{2} and \textcircled{3}) in response to the first read request RRQ1. That is, the controller 130 may provide a first read command RC1 and a first physical address AD1 to the nonvolatile memory device 140 (\textcircled{2}). Then, the nonvolatile memory device 140 may transmit first read data RD1, stored in a region corresponding to the provided first physical address AD1, to the controller 130 (\textcircled{3}). The controller 130 may transmit the first read data RD1 to the host device 110 (\textcircled{4}).

The data storage device 120 may perform a prefetch operation (process of \textcircled{2}′ and \textcircled{3}′ before receiving a second read request RRQ2 from the host device 110. The controller 130 may provide a read command PC and a physical address PAD corresponding to a prefetch range to the nonvolatile memory device 140 (\textcircled{2}′). The nonvolatile memory device 140 may transmit prefetch data PD to the controller 130 (\textcircled{3}′). The controller 130 may store the transmitted prefetch data PD in the working memory 135 until the second read request RRQ is received.

The data storage device 120 may receive the second read request. RRQ2 from the host device 110 (\textcircled{5}). When the second read request RRQ2 is a request for the prefetch data PD, the controller 130 may transmit the prefetch data PD stored in the working memory 135 (\textcircled{6}).

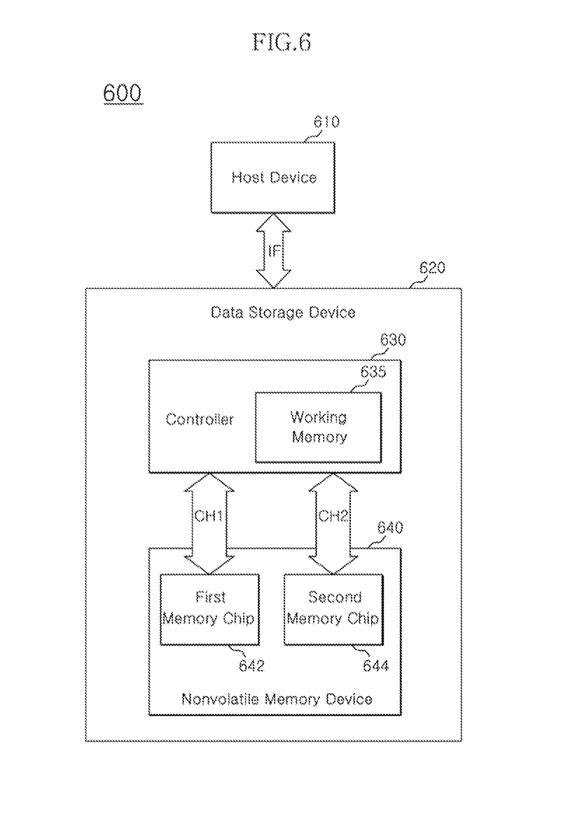

FIG. 6 is a block diagram illustrating a data processing system 600 including a data storage device 620 according to an embodiment of the present invention. Referring to FIG. 6, the data processing system 600 may include a host device 610 and the data storage device 620. The data storage device 620 may include a controller 630 and a nonvolatile memory device 640.

The nonvolatile memory device 640 may include a plurality of memory chips. FIG. 6 exemplary illustrates that the nonvolatile memory device 640 includes two memory chips 642 and 644. The memory chips 642 and 644 and the controller 630 may be coupled through channels CH1 and CH2, respectively. The memory chips 642 and 644 and the controller 630 may exchange a read or write command or data through the respective channels CH1 and CH2.

The controller 630 may perform a read operation on the nonvolatile memory device 640 based on a read request and a logical address the host device 610. The controller 630 may determine whether one or more physical addresses corresponding to one or more logical addresses continuous to the logical address are continuous to a physical address of any one of the two memory chips 642 and 644, which corresponds to the logical address. When one or more physical addresses are continuous, the controller 630 may prefetch data of a region corresponding to one or more physical addresses. At this time, the prefetch range may correspond to the other one of the two memory chips 642 and 644, for example, the second memory chip 644. In this case, the controller 630 may provide a read command and a physical address corresponding to the prefetch range to the second memory chip 644 in an interleaving method.

Except for such characteristics, the data storage device 620 may have the same configuration and operation as the data storage device 120 shown in FIG. 1 and perform the same operation the data storage device 120. Thus, the detailed descriptions thereof are omitted herein.

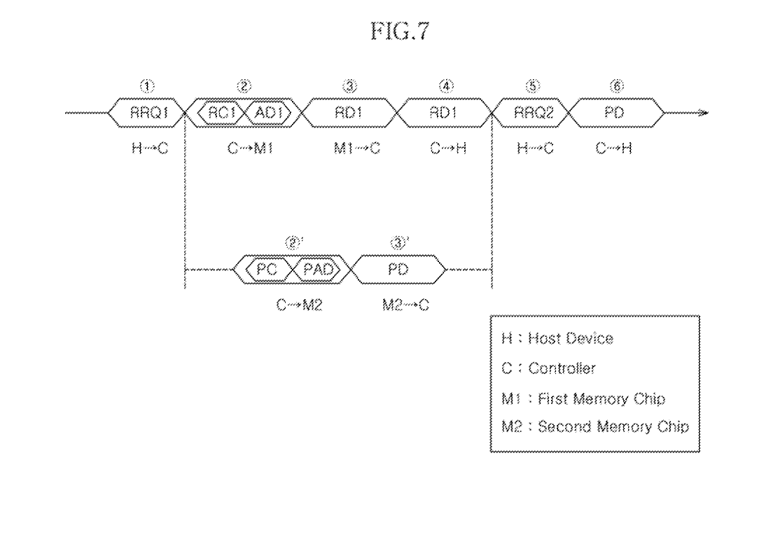

FIG. 7 is a timing diagram for explaining an operating method of a data processing system including the data storage device according to the embodiment of the present invention. FIG. 7 illustrates a read operation of the data processing system 600 shown in FIG. 6. In FIG. 7, it is assumed that the data storage device 620 determined to perform a prefetch operation according to the process described with reference to FIG. 3. Thus, the data storage device 620 may perform a normal read operation and a prefetch operation. FIG. 7 illustrates that the controller 630 provides one read command PC and one address PAD when performing the prefetch operation. However, when the prefetch range is set to a plurality of physical addresses, the controller 630 may provide read commands PC for the respective physical addresses.

Hereafter, the operating method of the data storage device 620 will be described in detail with reference to FIGS. 6 and 7.

The data storage device 620 may receive a first read request RRQ1 from the host device 610 (\textcircled{1}). The controller 630 may perform a normal read operation (process of \textcircled{2} and \textcircled{3}) in response to the first read request RRQ1. That is, the controller 630 may provide a read command RC1 and a first physical address AD1 to a corresponding memory chip of the nonvolatile memory device 640, for example, the first memory chip 642 (\textcircled{2}). Then, the first memory chip 642 may transmit first read data RD1, stored in a region corresponding to the provided first physical address AD1, to the controller 640 (\textcircled{3}).

The controller 630 may transmit the first read data RD1 to the host device 610 (\textcircled{4}).

The data storage device 620 may perform a prefetch operation (process of \textcircled{2}′ and \textcircled{3}′) before receiving a second read request RRQ2 from the host device 610. The controller 630 may provide a read command PC and a physical address PAD corresponding to a prefetch range to a corresponding memory chip of the nonvolatile memory device 640, for example, the second memory chip 644 (\textcircled{2}′). The second memory chip 644 may transmit prefetch data PD to the controller 630 (\textcircled{3}′). The controller 630 may store the transmitted prefetch data PD in the working memory 635 until the second read request RRQ2 is received. When the prefetch data PD and the first read data RD1 are stored in different memory chips, the prefetch operation (process of \textcircled{2}′ and \textcircled{3}′) of the data storage device 620 may be performed at the same time as the normal read operation (process of \textcircled{2} and \textcircled{3}).

The data storage device 620 may receive the second read request RRQ2 from the host device 610 (\textcircled{5}). When the second read request RRQ2 is a request for the prefetch data PD, the controller 630 may transmit the prefetch data PD stored in the working memory 635 (\textcircled{6}).

Therefore, the data processing system including the data storage device according to the embodiment of the present invention may quickly perform a read operation.

While certain embodiments have been described above, it will be understood to those skilled in the art that the embodiments described are by way of example only. Accordingly, the data storage device described herein should not be limited based on the described embodiments. Rather, the data storage device described herein should only be limited in light of the claims that follow when taken in conjunction with the above description and accompanying drawings.

What is claimed is:

1. An operating method of a data storage device, comprising:
performing a read operation on a nonvolatile memory device based on a read request and a logical address from a host device;
determining whether one or more physical addresses, which correspond to one or more logical addresses continuous to the logical address, are continuous to a physical address corresponding to the logical address; and
prefetching data stored in a region of the nonvolatile memory device, corresponding to the one or more physical addresses, when the one or more physical addresses are determined to be continuous.

2. The operating method according to claim 1, wherein the prefetching of the data comprises:
checking a range in which the one or more physical addresses are continuous; and
setting the range of the continuous physical addresses to a prefetch range.

3. The operating method according to claim 2, wherein the prefetching of the data further comprises:
providing a read command and a physical address corresponding to the prefetch range to the nonvolatile memory device.

4. The operating method according to claim 1, wherein the prefetching of the data further comprises:
storing data to be prefetched in a working memory.

5. The operating method according to claim 4, wherein the prefetched data are stored in the working memory, until a read request for the one or more continuous logical addresses is received from the host device.

6. The operating method according to claim 1, further comprising:
receiving a read request for the one or more continuous logical addresses from the host device, after the prefetching of the data.

7. The operating method according to claim 6, further comprising:
transmitting the prefetched data to the host device.

8. A data storage device comprising:
a nonvolatile memory device; and
a controller,
wherein the controller performs a read operation on the nonvolatile memory device based on a read request and a logical address from a host device, determines whether one or more physical addresses corresponding to one or more logical addresses continuous to the logical address are continuous to a physical address corresponding to the logical address, and prefetches data stored in a region of the nonvolatile memory device, corresponding to the one or more physical addresses, when the one or more physical addresses are determined to be continuous.

9. The data storage device according to claim 8, wherein the controller checks a range in which the one or more physical addresses are continuous, and sets the range of the continuous physical addresses to a prefetch range.

10. The data storage device according to claim 9, wherein the controller provides a read command and a physical address corresponding to the prefetch range to the nonvolatile memory device, and receives data to be prefetched from the nonvolatile memory device.

11. The data storage device according to claim 10, wherein the controller comprises:
a working memory suitable for storing the prefetched data until′ a read request for the one or more continuous logical addresses is received from the host device.

12. The data storage device according to claim 8, wherein the controller transmits the prefetched data when a read request for the one or more continuous logical addresses is received from the host device.

13. A data storage device comprising:
a plurality of nonvolatile memory chips; and
a controller,
wherein the controller performs a read operation on any one of the nonvolatile memory chips based on a read request and a logical address from a host device, determines whether one or more physical addresses corresponding to one or more logical addresses continuous to the logical address are continuous to a physical address corresponding to the logical address, and prefetches data of a region corresponding to the one or more physical addresses when the one or more physical addresses are determined to be continuous.

14. The data storage device according to claim 13, wherein the controller checks a range in which the one or more physical addresses are continuous, and sets the range of the continuous physical addresses to a prefetch range.

15. The data storage device according to claim 14, wherein the prefetch range includes a range corresponding to another nonvolatile memory chip.

16. The data storage device according to claim 15, wherein the controller provides a read command and a physical address corresponding to the prefetch range to another nonvolatile memory chip in an interleaving method, and receives data to prefetch from another nonvolatile memory chip.

17. The data storage device according to claim 16, wherein the controller comprises a working memory suitable for storing the prefetched data until a read request for the one or more continuous logical addresses is received from the host device.

18. The data storage device according to claim 1, wherein the controller transmits the prefetched data when a read request for the one or more continuous logical addresses is received from the host device.
